(19) United States
(12) Patent Application Publication
(10) Pub. No.: US 2005/0121736 A1
(43) Pub. Date: Jun. 9, 2005

(54) Receiver optical subassembly

(76) Inventors: Chiung-Hun Wang, Hsinchu (TW); Chun-Hsing Lee, Hsinchu (TW); Yi-Ming Chen, Hsinchu (TW); Shin-Ge Lee, Hsinchu (TW); Chih-Li Chen, Hsinchu (TW); Ming-Fa Huang, Hsinchu (TW); Chih-Hao Hsu, Hsinchu (TW)

Correspondence Address: BIRCH STEWART KOLASCH & BIRCH, PO BOX 747, FALLS CHURCH, VA, 22040-0747, US

(21) Appl. No.: 10/854,243

(22) Filed: May 27, 2004

(30) Foreign Application Priority Data
Dec. 5, 2003 (TW) 092134451

(51) Int. Cl. H01L 29/267; H01L 33/00

(52) U.S. Cl. 257/432; 257/433; 257/81; 257/82

(57) ABSTRACT

A receiver optical subassembly for transforming received optical signal into electrical signal includes at least a ceramic substrate, a photo receiver and a transimpedance amplifier. There are high-speed traces formed on the substrate. The positive and negative pads of the photo receiver are coplanar and connected to the traces without wire bonding so as to reduce the parasitic impedance effect and improve the high-speed performance of the optical subassembly. The transimpedance amplifier is electrically connected to the traces via flip chip, wire bonding or other methods. The photo receiver and the transimpedance amplifier are connected via the high-speed traces formed on the substrate.

### BACKGROUND OF THE INVENTION

1. Field of the Invention

The invention generally relates to an optical transmission module, and in particular relates to a receiver optical subassembly.

2. Related Art

In the trend of high transmission-rate communication, optical data transmission is being fast developed, and the related fiber optic products are getting more and more important. An optical data transmission system applying optical fiber media requires high transmission rate, low noise and of precise alignment of high quality optical transmission modules in order to meet user's needs. The key technologies for optical transmission modules are high-speed components, optical subassembly, alignment package and so on.

Currently, the optical transceivers are mainly of surface emitting and surface receiving elements, such as vertical cavity surface emitting lasers (VCSEL). The package of the optical transceiver has to provide good alignment of the transceiver and the lens in order to get precise and efficient transmission. A receiver optical subassembly in the optical transmission module has to meet the requirements of high precision, high transmission rate and low noise. Conventional receiver optical module is composed of metallic pad substrate and surface mounted capacitors. Other components are connected through wire mounting. In U.S. Pat. No. 5,610,395, a photoreceiver module uses a parallel plate capacitor (metal-insulator-metal, MIM capacitor) to replace the aforesaid substrate in order to reduce the package size and to simplify the steps of production.

Under the requirement of high coupling efficiency of laser source and optical fiber, the requirement of alignment is getting stricter. Currently, most optical communication elements are processed by active alignment that a light source passes into the module for executing semi-automatic mechanical alignments of relative positions of the components. The facilities and processes are rather complicated and time-consuming. In order to reduce the alignment cost, a passive alignment, such as that disclosed by U.S. Pat. No. 6,576,888, can be applied. A light-receiving module of the patent consists of a mount substrate, an optical fiber, a semiconductor photoreceiver, a mount member, and a signal processing semiconductor element. The mount substrate is placed between the pair of arm portions of the mount member and carries the optical fiber and the semiconductor photoreceiver. Because the optical fiber is located in an etched groove formed on the mount substrate, the precision of the groove greatly influences the alignment; also, the package gets a larger size, and the package process is more complicated.

Because the manufacturing process influences the construction and alignment precision of an optical subassembly, in order to improve the quality and yield rate of the product, the requirements on the process and facilities are getting stricter, and the costs are getting higher. Therefore, it is a demand to get an inventive optical subassembly package that meets the requirements of high transmission rate, low noise, effective component alignments, low cost and high yield rate.

### SUMMARY OF THE INVENTION

The object of the invention is to provide a receiver optical subassembly having an integrated package and performing effective alignment of optical transceiver elements. The optical subassembly has high performance and small size.

A receiver optical subassembly for transforming received optical signal into electrical signal according to the invention includes a substrate, a photoreceiver and a transimpedance amplifier. There are high-speed traces formed on the substrate. The positive and negative pads of the photoreceiver are coplanar and connected to the traces through flip chip so as to reduce the parasitic impedance effect and improve the high-speed performance of the optical subassembly. The transimpedance amplifier is electrically connected to the traces via flip chip, wire bonding or other methods. The photoreceiver and the transimpedance amplifier are connected via the high-speed traces formed on the ceramic substrate.

The invention further includes a base and a metal case for packing aforesaid substrate, photoreceiver and transimpedance amplifier. The base includes a plurality of electrical pins including a ground pin. The substrate has grounding pad electrically connects with the ground pin for reducing crosstalk and other interferences generated by high frequency signals. The metal case and the base form a shield for the substrate, the photoreceiver and the transimpedance amplifier. The grounding pin connects to the metal case for good shielding. Electrical signals are connected outwards via the electrical pins passing through the bottom of the base.

In order to improve the coupling efficiency, the light-receiving surface of the photoreceiver is formed with a micro lens. In accompany with some external coupling elements, the beam coupling system is decreased with requirements of alignment precision and improved with coupling efficiency.

### BRIEF DESCRIPTION OF THE DRAWINGS

The invention will become more fully understood from the detailed description given hereinbelow. However, this description is for purposes of illustration only, and thus is not limitative of the invention, wherein:

FIG. 1 is a constructional view of a photoreceiver and a transimpedance amplifier in an embodiment of the invention;

FIG. 2 is a constructional view of a substrate and a base in an embodiment of the invention; and

FIG. 3 is an application view of an embodiment of the invention.

### DETAILED DESCRIPTION OF THE INVENTION

In the invention, the anode and cathode of the photoreceiver are coplanar (i.e. back-received photodidoe) and connected to the traces so as to reduce the parasitic impedance effect, improve the high speed performance of the optical subassembly and reduce the package size.

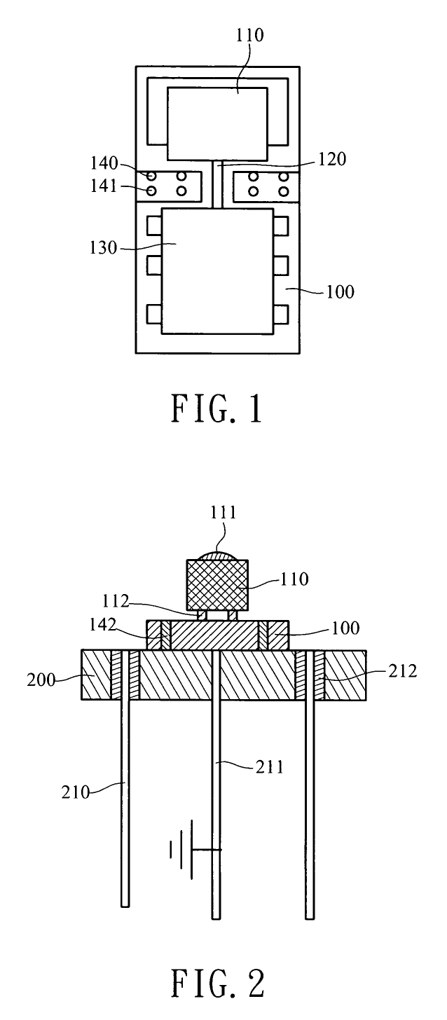

As shown in FIG. 1, a constructional view of a photodiode and a transimpedance amplifier in an embodiment of the invention, the photodiode 110 and the transimpedance amplifier 130 are electrically connected to the high-speed traces 120 formed on surface of the ceramic substrate 100. The positive and negative pins of the photodiode 110 are coplanar and connected to the high-speed traces 120. The transimpedance amplifier 130 is electrically connected to the high-speed traces 120 via flip chip, wire bonding or other methods. The high-speed traces 120 connected between the photodiode 110 and the transimpedance amplifier 130 surround with the ground pads 140. The ground pads 140 also electrically connect downwards to the ground pin of the base via some grounding through holes 141 of the ceramic substrate 100 in order to reduce crosstalk. The ceramic substrate 100 can be formed with an alignment key so that the photoreceiver can be easily aligned.

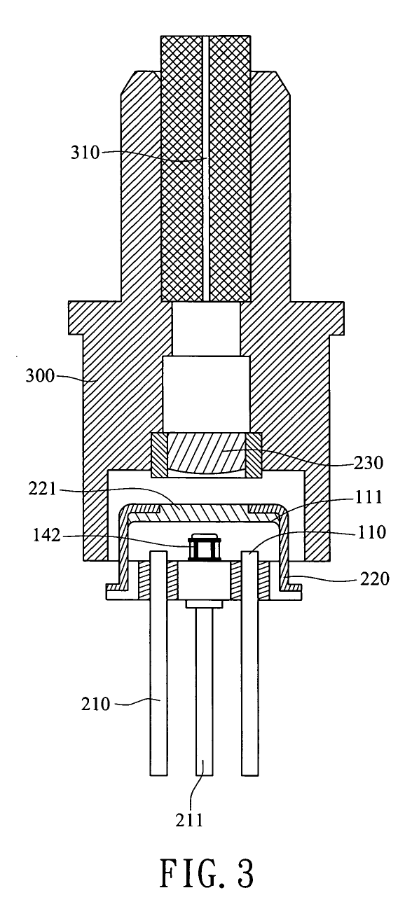

A base 200 can be made with a grounding structure for improving the performance of the optical subassembly. The constructional view of the substrate 100 and the base 200 of the receiver optical subassembly is shown in FIG. 2. The ceramic substrate 100 is mounted on the base 200. The base 200 includes a plurality of electrical pins 210 including a ground pin 211. The ceramic substrate 100 has grounding pads 140 electrically connect with the ground pin 211 for reducing crosstalk and other interferences generated by high frequency signals. In order to lower the requirements of alignment precision, the light-receiving surface of the photodiode 110 is formed with a micro lens 111. The bottom of the photodiode 110 is connected through tin balls 112 to the ceramic substrate 100. The ceramic substrate 100 connects to the base 200 through a conductive via hole 142. The electrical pins 210, except the ground pin 211, of the base 200 are shielded with glass 212. A metal case 220 (referred to FIG. 3) and the base 200 form a shield for the substrate, the photoreceiver and the transimpedance amplifier 130. The grounding pin 211 electrically connects to the base 200, the substrate 100 and a metal case for good shielding.

The metal case 220 incorporates the grounding pin of the base 200 for shielding the substrate 100, the photodiode 110 and the transimpedance amplifier 130. A coupling structure of application with an optical fiber connector is illustrated in FIG. 3. The grounding pin 211 is connected to the metal case 220 for good shield. The electrical signals are connected outwards via the grounding pin 211 passing through the bottom of the base 200. In accompany with an external coupling elements 310 with the micro lens 111 of the photodiode 110, the beam coupling system lowers the requirements of alignment precision and improves the coupling efficiency. One end of the optical fiber connector 300 is coupled to the metal case 220. A light-receiving portion 221 of the metal case 220 is a transparent piece or a lens for incidental beams to pass to the photodiode 110. The other end of the optical fiber connector 300 receives the optical fiber 310. A first beam coupler 230 is mounted between the optical fiber 310 and the light-receiving portion 221 of the metal case 220 so that the incidental beam comes from the optical fiber 310 to the beam coupler 230, the light-receiving portion 221 and the photodiode 110 sequentially. A second beam coupler (not shown in the drawing) may also be mounted on the light-receiving portion 221 of the metal case 220 in order to couple or collect the beam. The optical fiber connector 300 can also be coupled with the metal case to form a better shield.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A receiver optical subassembly for transforming received optical signal into electrical signal, comprising:
a substrate, formed thereon high-speed traces;
a photoreceiver, having a positive pad, a negative pad and a light-receiving surface; said positive and negative pads are coplanar, said photoreceiver is connected to said traces; and
a transimpedance amplifier, electrically connected to said traces, said photoreceiver and said transimpedance amplifier are connected via said high-speed traces.

2. The receiver optical subassembly of claim 1 wherein said photoreceiver is a photodiode.

3. The receiver optical subassembly of claim 1 wherein said transimpedance amplifier is connected to said high-speed traces through flip chip.

4. The receiver optical subassembly of claim 1 wherein said transimpedance amplifier is connected to said high-speed traces through wire bonding.

5. The receiver optical subassembly of claim 1 wherein surface of said substrate is formed with an alignment key.

6. The receiver optical subassembly of claim 1 further comprises a micro lens mounted on said light-receiving surface.

7. The receiver optical subassembly of claim 1 is mounted on a base where a plurality of electrical pins, including a ground pin, are formed.

8. The receiver optical subassembly of claim 7 wherein high-speed traces connecting said photoreceiver and said transimpedance amplifier surrounds with ground pads; said ground pads connect to said ground pin via a plurality of grounding through holes formed on said substrate.

9. A receiver optical subassembly for transforming received optical signal into electrical signal, comprising:
A base, having a plurality of electrical pins;
a substrate, mounted on said base and formed with high-speed traces;
a photoreceiver, having a positive pad, a negative pad and a light-receiving surface; said positive and negative pads are coplanar; said photoreceiver is connected to said traces; and
a transimpedance amplifier, electrically connected to said traces; said photoreceiver and said transimpedance amplifier are connected via said high-speed traces; said photoreceiver and said transimpedance amplifier are also connected to said electrical pins.

10. The receiver optical subassembly according to claim 9 wherein said photoreceiver is a photodiode.

11. The receiver optical subassembly of claim 9 wherein said transimpedance amplifier is connected to said high-speed traces through flip chip.

12. The receiver optical subassembly of claim 9 wherein said transimpedance amplifier is connected to said high-speed traces through wire bonding.

13. The receiver optical subassembly of claim 9 wherein surface of said substrate is formed with an alignment key.

14. The receiver optical subassembly of claim 9 further comprises a micro lens mounted on said light-receiving surface.

15. The receiver optical subassembly of claim 9 wherein said plurality of electrical pins comprises a ground pin.

16. The receiver optical subassembly of claim 15 wherein high-speed traces connecting said photoreceiver and said transimpedance amplifier surrounds with ground pads; said ground pads connect to said ground pin via a plurality of grounding through holes formed on said substrate.

17. The receiver optical subassembly of claim 9 further comprises a metal case mounted on said base; said metal case is formed with a light-receiving portion for incidental beams to pass to said photoreceiver.

18. The receiver optical subassembly of claim 17 further comprises an optical fiber connector having one end connected to said metal case, and another end connected to said optical fiber.

19. The receiver optical subassembly of claim 18 further comprises a first beam coupler mounted between said optical fiber and said light-receiving portion.

20. The receiver optical subassembly of claim 17 wherein said light-receiving portion is a lens.

21. The receiver optical subassembly of claim 17 wherein said light-receiving portion is a transparent piece.

22. The receiver optical subassembly of claim 17 further comprises a second beam coupler mounted on said light-receiving portion.
